(19) United States
(12) Patent Application Publication
(10) Pub. No.: US 2024/0162129 A1
(43) Pub. Date: May 16, 2024

(54) SUBSTRATE ARRANGEMENT AND METHODS FOR PRODUCING A SUBSTRATE ARRANGEMENT

(71) Applicant: Infineon Technologies AG, Neubiberg (DE)

(72) Inventors: Christoph Bayer, Eußenheim (DE); Michael Fügl, Neumarkt (DE); Frank Singer, Regenstauf (DE); Thorsten Meyer, Regensburg (DE); Fabian Craes, Soest (DE); Andreas Grassmann, Sinzing (DE); Frederik Otto, Olfen (DE)

(21) Appl. No.: 18/504,309

(22) Filed: Nov. 8, 2023

(30) Foreign Application Priority Data
Nov. 16, 2022 (EP) 22207915.4

(51) Int. Cl. H01L 23/498; B82Y 10/00; H01L 23/00; H01L 23/31; H01L 25/07

(52) U.S. Cl. CPC H01L 23/49811; B82Y 10/00; H01L 23/3135; H01L 23/49822; H01L 23/49844; H01L 24/32; H01L 24/48; H01L 24/73; H01L 25/072; H01L 2224/32245; H01L 2224/48245; H01L 2224/73265; H01L 2924/1203; H01L 2924/13055; H01L 2924/13062; H01L 2924/13064; H01L 2924/13091; H01L 2924/181

(57) ABSTRACT

A substrate arrangement includes: a first metallization layer, nanowires arranged on a surface of the first metallization layer; and a component arranged on the first metallization layer such that a first subset of the nanowires is arranged between the first metallization layer and the component. The nanowires are evenly distributed over a section of the surface area or over the entire surface area of the first metallization layer. Each nanowire includes first and second ends. The first end of each nanowire is inseparably connected to the surface of the first metallization layer. The second end of each nanowire of the first subset is inseparably connected to a surface of one of the component such that the first subset of nanowires forms a permanent connection between the first metallization layer and the component. There are fewer nanowires in the first subset of nanowires than there are total nanowires.

### TECHNICAL FIELD

The instant disclosure relates to a substrate arrangement, in particular to a substrate arrangement for a power semiconductor module arrangement, and to methods for producing such a substrate arrangement.

### BACKGROUND

Power semiconductor module arrangements often include at least one semiconductor substrate arranged in a housing. A semiconductor arrangement including a plurality of controllable semiconductor elements (e.g., two IGBTs in a half-bridge configuration) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer may optionally be attached to a base plate or heat sink.

There is a need for a substrate arrangement that allows to securely mount elements thereon in a simple manner.

### SUMMARY

A substrate arrangement comprises a first metallization layer, a plurality of nanowires arranged on a surface of the first metallization layer, and at least one component arranged on the first metallization layer such that a first subset of the plurality of nanowires is arranged between the first metallization layer and the at least one component, wherein the plurality of nanowires is evenly distributed over a section of the surface area or over the entire surface area of the first metallization layer, each of the plurality of nanowires includes a first end and a second end, wherein the first end of each of the plurality nanowires is inseparably connected to the surface of the first metallization layer, the second end of each nanowire of the first subset is inseparably connected to a surface of one of the at least one component such that the first subset of nanowires forms a permanent connection between the first metallization layer and the at least one component, the at least one component comprises at least one semiconductor body, and the number of nanowires comprised in the first subset of nanowires is less than the number of nanowires comprised in the plurality of nanowires.

A method includes forming a first metallization layer, forming a plurality of nanowires on a surface of the first metallization layer, and arranging at least one component on the first metallization layer such that a first subset of the plurality of nanowires is arranged between the first metallization layer and the at least one component, wherein the plurality of nanowires is evenly distributed over a section of the surface area or over the entire surface area of the first metallization layer, each of the plurality of nanowires includes a first end and a second end, wherein the first end of each of the plurality nanowires is inseparably connected to the surface of the first metallization layer, the second end of each nanowire of the first subset is inseparably connected to a surface of one of the at least one component such that the first subset of nanowires forms a permanent connection between the first metallization layer and the at least one component, the at least one component comprises at least one semiconductor body, and the number of nanowires comprised in the first subset of nanowires is less than the number of nanowires comprised in the plurality of nanowires.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a power semiconductor module arrangement.

FIGS. 2A and 2B schematically illustrate a method for attaching two connection partners to each other.

FIGS. 3A and 3B schematically illustrate another method for attaching two connection partners to each other.

FIG. 4 is a cross-sectional view of a substrate arrangement according to one example.

FIG. 5A to 5C schematically illustrate a method for forming a substrate arrangement according to one example.

FIGS. 6A to 6C schematically illustrate a method for forming a substrate arrangement according to another example.

FIGS. 7A to 7D schematically illustrate a method for forming a substrate arrangement according to an even further example.

FIG. 8 is a cross-sectional view of a substrate arrangement according to another example.

FIG. 9 is a cross-sectional view of a substrate arrangement according to one example with an encapsulant arranged thereon.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

Referring to FIG. 1, a cross-sectional view of a power semiconductor module arrangement 100 is schematically illustrated. The power semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 is arranged on a base plate 12 which forms a ground surface of the housing 7, while the housing 7 itself solely comprises sidewalls and a cover or lid. This is, however, only an example. It is also possible that the housing 7 further comprises a ground surface and the substrate 10 and the base plate 12 be arranged inside the housing 7. In some power semiconductor module arrangements 100, more than one substrate 10 is arranged on a single base plate 12 or on the ground surface of a housing 7. It is, however, also possible that the power semiconductor module arrangement 100 does not comprise a base plate 12 at all. For example, the substrate 10 may form a ground surface of the housing 7 instead. It is also possible that the housing 7 comprises a ground surface, sidewalls and a cover, and one or more substrates 10 are arranged on the ground surface and inside the housing 7. That is, the power semiconductor module arrangement may be an arrangement comprising a base plate 12, or a base plate-less power semiconductor module arrangement 100.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), and/or any other suitable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes three different sections. This, however, is only an example. Any other number of sections is possible. Different semiconductor bodies 20 may be mounted to the same or to different sections of the first metallization layer 111. Different sections of the first metallization layer 111 may have no electrical connection or may be electrically connected to one or more other sections using electrical connections 3 such as, e.g., bonding wires. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer 30 may be a solder layer, a layer of an electrically conductive adhesive, or a layer of a sintered metal powder, e.g., a sintered silver powder, for example.

According to other examples, it is also possible that the second metallization layer 112 is a structured layer. It is further possible to omit the second metallization layer 112 altogether. It is generally also possible that the first metallization layer 111 is a continuous layer, for example.

The power semiconductor module arrangement 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of each of the terminal elements 4 protrudes out of the housing 7. The terminal elements 4 may be electrically contacted from the outside at their respective second ends 42. A first part of the terminal elements 4 may extend through the inside of the housing 7 in a vertical direction y. The vertical direction y is a direction perpendicular to a top surface of the substrate 10, wherein the top surface of the substrate 10 is a surface on which the at least one semiconductor body 20 is mounted. The terminal elements 4 illustrated in FIG. 1, however, are only examples. Terminal elements 4 may be implemented in any other way and may be arranged anywhere within the housing 7. For example, one or more terminal elements 4 may be arranged close to or adjacent to the sidewalls of the housing 7. Terminal elements 4 could also protrude through the sidewalls of the housing 7 instead of through the cover. The first end 41 of a terminal element 4 may be electrically and mechanically connected to the substrate 10 by an electrically conductive connection layer, for example (not explicitly illustrated in FIG. 1). Such an electrically conductive connection layer may be a solder layer, a layer of an electrically conductive adhesive, or a layer of a sintered metal powder, e.g., a sintered silver (Ag) powder, for example. The first end 41 of a terminal element 4 may also be electrically coupled to the substrate 10 via one or more electrical connections 3, for example. For example, the second ends 42 of the terminal elements 4 may be connected to a printed circuit board that is arranged outside of the housing 7 (not illustrated in FIG. 1).

The power semiconductor module arrangement 100 further includes an encapsulant 5. The encapsulant 5 may consist of or include a silicone gel or may be a rigid molding compound, for example. The encapsulant 5 may at least partly fill the interior of the housing 7, thereby covering the components and electrical connections that are arranged on the substrate 10. The terminal elements 4 may be partly embedded in the encapsulant 5. At least their second ends 42, however, are not covered by the encapsulant 5 and protrude from the encapsulant 5 through the housing 7 to the outside of the housing 7. The encapsulant 5 is configured to protect the components and electrical connections of the power semiconductor module 100, in particular the components arranged on the substrate 10 inside the housing 7, from certain environmental conditions and mechanical damage.

As has been described above, different components (e.g., semiconductor bodies 20, terminal elements 4 or any other components) may be mounted to the substrate 10 (i.e. the first metallization layer 111) by means of an electrically conductive connection layer 30. Such an electrically conductive connection layer 30, however, may have several drawbacks. For example, a plurality of different steps may have to be performed when forming an electrically conductive connection layer 30 (e.g., solder layer, a layer of an electrically conductive adhesive, or a layer of a sintered metal powder).

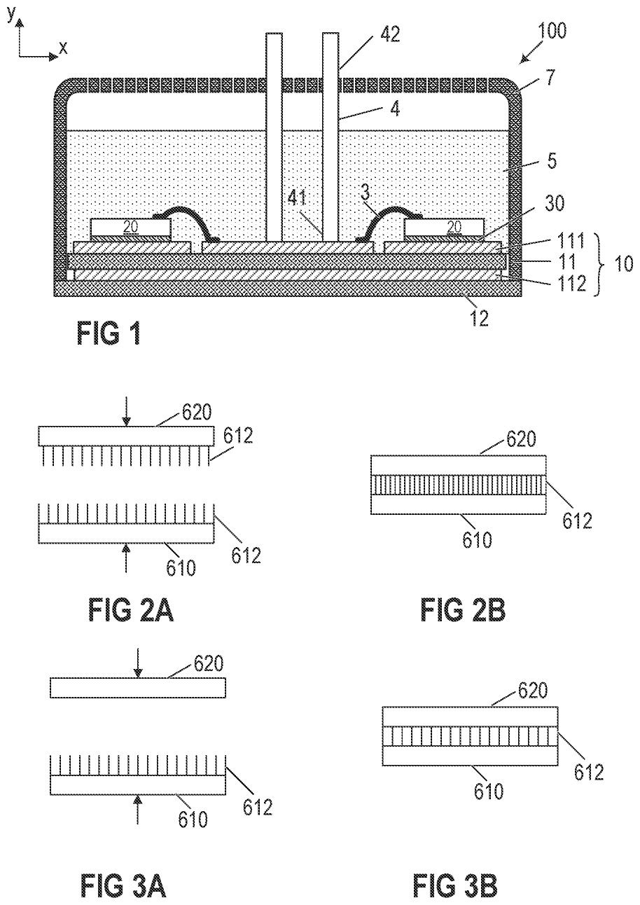

Now referring to FIGS. 2A and 2B, a first connection partner 610 and a second connection partner 620 are schematically illustrated. The first connection partner 610 may be a substrate for a power semiconductor module, for example. The second connection partner 620 may be a semiconductor body, a terminal element, or any other component that is to be mounted to the substrate, for example. It is, however, also possible that the first connection partner 610 is a heat sink or base plate, and the second connection partner 620 is a substrate. A plurality of nanowires 612 is formed on a surface of the first connection partner 610 which faces the second connection partner 620. A second plurality of nanowires 612 is formed on a surface of the second connection partner 620 which faces the first connection partner 610. Each of the plurality of nanowires 612 has a first end and a second end. A first end of each of the plurality of nanowires 612 is inseparably connected to the surface of the first connection partner 610. A first end of each of the second plurality of nanowires 612 is inseparably connected to the surface of the second connection partner. The first and second connection partners 610, 620 are arranged at a certain distance from each other. The second ends of the plurality of nanowires 612 and the second ends of the second plurality of nanowires 612 are free ends. The surface of the first connection partner 610 on which the plurality of nanowires 612 is formed and the surface of the second connection partner 620 on which the second plurality of nanowires 612 is formed may consist of the same material such as, e.g., Al, an Al alloy, Cu, a Cu alloy, Ag, an Ag alloy, Au, or an Au alloy.

The first connection partner 610 and the second connection partner 620 are then moved towards each other such that the second ends of the plurality of nanowires 612 contact the surface of the second connection partner 620, and the second ends of the second plurality of nanowires 612 contact the surface of the first connection partner 610. Under the influence of pressure and heat, the second ends of the plurality of nanowires 612 may be inseparably connected to the surface of the second connection partner 620, and the second ends of the second plurality of nanowires 612 may be inseparably connected to the surface of the first connection partner 610. In this way, a permanent connection between the first connection partner 610 and the second connection partner 620 may be formed by means of the nanowires 612.

The term nanowires 612 as used herein designates any element having the form of a wire, i.e. a length that is several times larger than its diameter, wherein the dimensions of the element are in the nanometer range. For example, so-called nanotubes or nanorods may also be used and are considered to fall under the term nanowire as used herein. Generally speaking, a nanowire 612 is a nanostructure in the form of a wire having a nanorange diameter. For example, a diameter of a nanowire 612 may be between 500 nm and 1200 nm. The nanowires 612 may have a length between their first end and their second end of between 10 μm and 70 μm, for example. The nanowires 612 generally extend perpendicular to the surface on which they are formed. Therefore, all nanowires 612 may have the same length such that the second ends of all of the nanowires 612 extend all the way to the surface of the other connection partner. The nanowires 612 may comprise or consist of carbon, cobalt, copper, silicon, or gold, for example.

Nanowires 612 may be formed by any suitable process such as, e.g., (chemical) vapor deposition, suspension, electrochemical deposition, VLS growth (VLS=Vapor-liquid-solid method), and ion track technology.

In the example illustrated in FIGS. 2A and 2B, the first and the second connection partners 610, 620 are each provided with nanowires 612. This, however, is only an example. As is schematically illustrated in FIG. 3A, it is also possible to form nanowires 612 only on one of the two connection partners. In the example illustrated in FIG. 2B, the plurality of nanowires 612 formed on the first connection partner 610 and the second plurality of nanowires 612 formed on the second connection partner 620 can be considered to intertwine when the first and second connection partner 610, 620 are arranged close enough to each other and a permanent connection is formed between the two connection partners 610, 620. This is not the case in the example of FIG. 3B, because no nanowires 612 are formed on the surface of the second connection partner 620. However, with the plurality of nanowires 612 formed on the first connection partner 610, it is still possible to form a permanent connection between the first connection partner 610 and the second connection partner 620. The stability of the connection, however, may be further improved if nanowires 612 are provided on both surfaces.

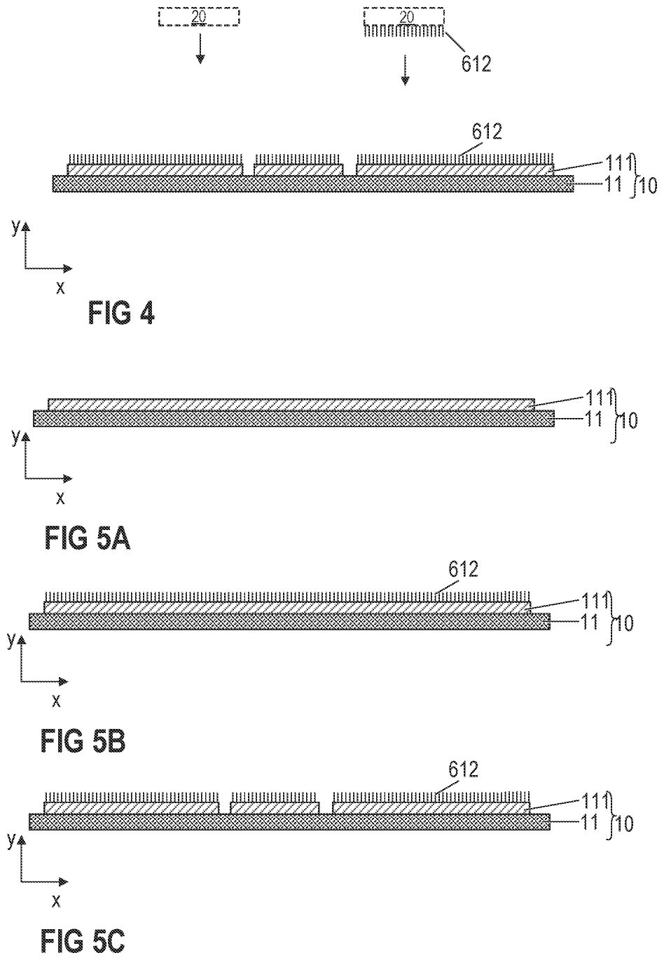

Now referring to FIG. 4, a substrate arrangement according to one example is schematically illustrated. The substrate arrangement may comprise a substrate 10, similar to what has been described with respect to FIG. 1 above. The dielectric insulation layer 11, however, may also be omitted. The metallization layer 111, for example, may also be a so-called lead frame (die pad). That is, the substrate arrangement may solely comprise a metallization layer 111 and no dielectric insulation layer 11. The substrate 10 that is schematically illustrated in FIG. 4 comprises a dielectric insulation layer 11 and a first metallization layer 111 attached to a first side of the dielectric insulation layer 11. The substrate 10, optionally, may further comprise a second metallization layer (not specifically illustrated in FIG. 4). The substrate arrangement further comprises a plurality of nanowires 612 arranged on a surface of the first metallization layer 111. If the metallization layer 111 is arranged on a dielectric insulation layer 11, the plurality of nanowires 612 is arranged on a surface of the first metallization layer 111 that faces away from the dielectric insulation layer 11. The plurality of nanowires 612 is evenly distributed over a section of the surface area or over the entire surface area of the first metallization layer 111. That is, the number of nanowires 612 per unit area is the same over at least a section of the entire surface area of the first metallization layer 111. According to one example, the section of the surface area of the first metallization layer 111 covered by the plurality of nanowires 612 is between 60% and 100%, or between 70% and 100% of the entire surface area of the first metallization layer 111. In the example illustrated in FIG. 4, the first metallization layer 111 is a structured layer. All of the different sections of the first metallization layer 111 may be entirely covered by nanowires 612. It is, however, also possible that one or more, but not all sections of the first metallization layer 111 remain free of nanowires 612. Additionally or alternatively it is also possible that one or more sections are only partly covered by nanowires 612.

The nanowires 612 are generally formed on the first metallization layer 111 before any components (e.g., semiconductor bodies 20, terminal elements 4, or any other components) are arranged on the substrate 10. By covering at least a (large) section or even the entire surface area of the first metallization layer 111 with nanowires 612, the substrate 10 may be equipped with components very flexibly. The section that is covered by the nanowires 612 is larger than the area required for mounting the components 20, 4 to the metallization layer 111. In this way, the components that are to be arranged on the substrate 10 do not have to be mounted to any specifically dedicated areas. That is, the substrate arrangement can be sold to different customers, irrespective of the specific design of the customer. Or the same customer may use the same substrate for different designs without the need for any adaptions or customizations. After any semiconductor bodies 20 and/or other components have been mounted to the substrate 10, a different subset of the plurality of nanowires 612 is arranged between each of the at least one component 20, 4 and the first metallization layer 111, wherein the second end of each nanowire 612 of the at least one subset is inseparably connected to a surface of the respective component 20, 4 such that each subset of nanowires 612 forms a permanent connection between the respective component 20, 4 and the first metallization layer 111.

The number of nanowires 612 comprised in the at least one subset of nanowires 612, however, is less than the number of nanowires 612 comprised in the plurality of nanowires 612. That is, the second ends of at least one other subset of nanowires 612 are free ends that are not connected to any component 20, 4.

A method for producing a substrate arrangement according to one example comprises forming a first metallization layer 111, forming a plurality of nanowires 612 on a surface of the first metallization layer 111, and arranging at least one component 20, 4 on the first metallization layer 111 such that a first subset of the plurality of nanowires is arranged between the first metallization layer and the at least one component, wherein the plurality of nanowires 612 is evenly distributed over a section of the surface area or over the entire surface area of the first metallization layer 111, each of the plurality of nanowires 612 comprises a first end and a second end, wherein the first end of each of the plurality nanowires 612 is inseparably connected to the surface of the first metallization layer 111, the second end of each nanowire of the first subset is inseparably connected to a surface of one of the at least one component 20, 4 such that the first subset of nanowires forms a permanent connection between the first metallization layer 111 and the at least one component 20, 4, the at least one component comprises at least one semiconductor body 20, and the number of nanowires 612 comprised in the first subset of nanowires 612 is less than the number of nanowires 612 comprised in the plurality of nanowires 612.

In the example illustrated in FIGS. 5A to 5C, a substrate 10 comprising a dielectric insulation layer 11 and a continuous first metallization layer 111 is provided (FIG. 5A), and the plurality of nanowires 612 is formed on the continuous first metallization layer 111 (FIG. 5B). The first metallization layer 111 in this example is only structured after forming the plurality of nanowires 612, as is schematically illustrated in FIG. 5C.

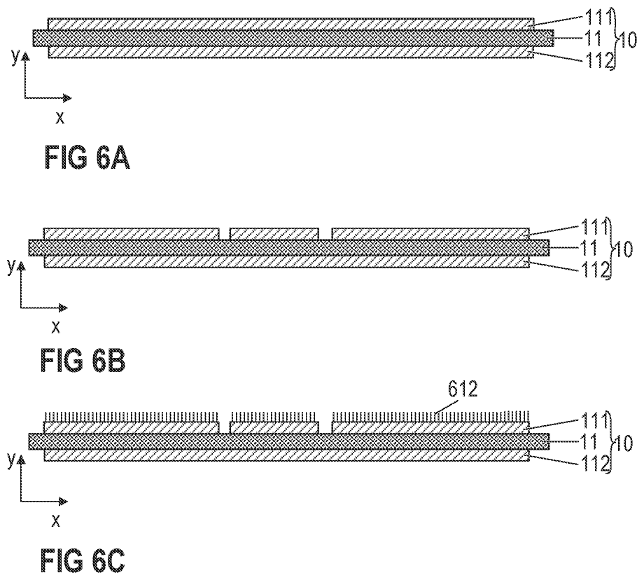

According to another example, however, and as is schematically illustrated in FIGS. 6A to 6C, it is alternatively also possible to provide a substrate 10 comprising a dielectric insulation layer 11 and a continuous first metallization layer 111 (FIG. 6A), and to structure the first metallization layer 111 (FIG. 6B) before forming the plurality of nanowires 612 (FIG. 6C). When structuring the first metallization layer 111, two or more separate sections and recesses between different sections of the first metallization layer 111 are formed.

As has been described above, different methods can be used to form the nanowires 612. With most methods, nanowires 612 can only be formed on metallic surfaces. Therefore, if the first metallization layer 111 is structured first, as is exemplarily illustrated in FIGS. 6A to 6C, generally no nanowires 612 will form on those sections of the dielectric insulation layer 11, which are no longer covered by the first metallization layer 111. As has been described with respect to FIG. 1 above, the dielectric insulation layer 11 generally does not comprise any metallic surfaces. Therefore, no nanowires 612 will grow on the surfaces of the dielectric insulation layer 11.

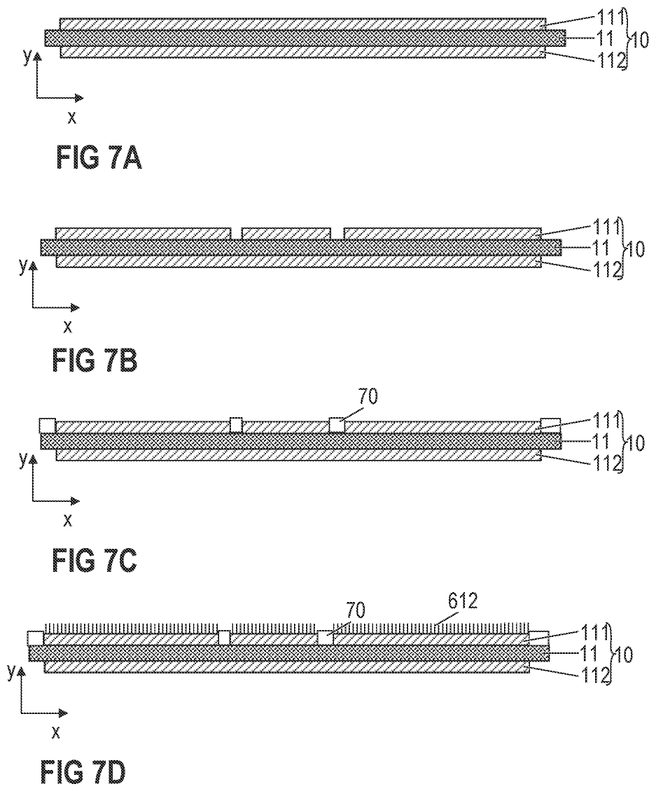

According to another example, however, it is also possible to form a masking layer 70 after structuring the first metallization layer (see FIGS. 7A and 7B) and before forming the plurality of nanowires 612, as is schematically illustrated in FIG. 7C. In particular, the masking layer 70 may be formed on those sections of the dielectric insulation layer 11 that are not covered by the first metallization layer 111, thereby preventing nanowires 612 from being formed on the dielectric insulation layer 11. Once the nanowires 612 have been formed (see FIG. 7D), the masking layer 70 may be removed (not specifically illustrated).

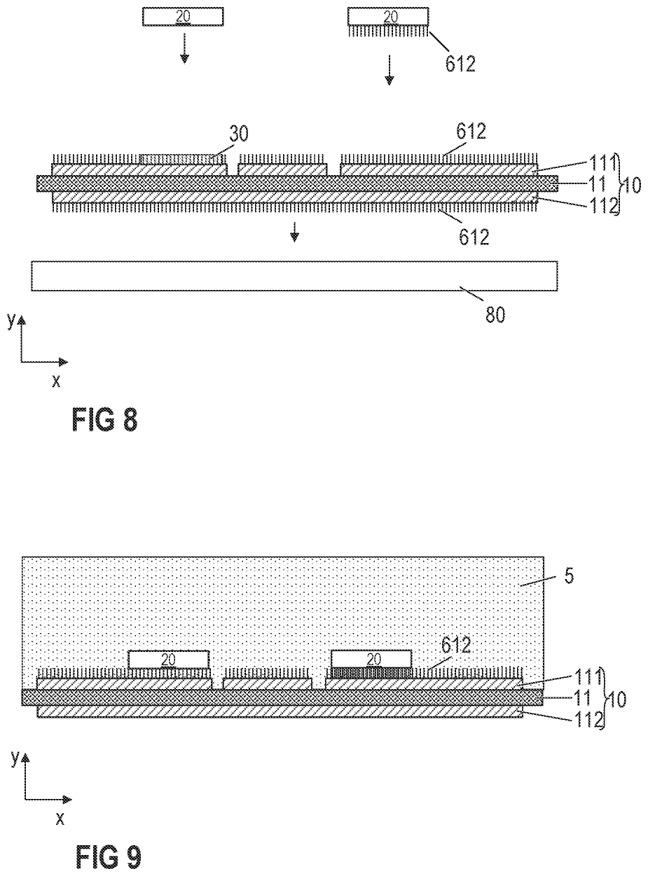

Now referring to FIG. 8, components such as, e.g., semiconductor bodies 20, may be mounted on the surface of the first metallization layer 111. Such components 20 may be fitted with nanowires 612 as well, as has been described with respect to FIGS. 2A and 2B above and as is exemplarily illustrated for the semiconductor body on the right hand side of FIG. 8. This, however, is not mandatory. As has been described with respect to FIGS. 3A and 3B above and as is exemplarily illustrated on the left hand side of FIG. 8, it is also possible that no nanowires 612 are formed on a surface of the component that is to be mounted to the substrate 10. As has been described with respect to FIGS. 2A-2B and 3A-3B above, the components may be mounted to the substrate 10 under the influence of heat and pressure. No additional solder pastes or sinter pastes are generally required. However, it is also possible to form an additional electrically conductive connection layer 30 between one or more of the components 20, 4 and the first metallization layer 111, similar to what has been described with respect to FIG. 1 above and as is schematically illustrated for the semiconductor body 20 on the left hand side of FIG. 8. Such an electrically conductive connection layer 30 may be formed only regionally. In particular, electrically conductive connection layers 30 may only be formed in those areas that are arranged between the first metallization layer 111 and one of the components 20, 4 mounted thereon. The material of the electrically conductive connection layer 30 fills any gaps or spaces between the respective ones of the nanowires 612 and may even further increase the strength of the connection formed between the first metallization layer 111 and the respective component 20, 4. This, however, is only optional. The strength of the connection is generally sufficient even without an additional electrically conductive connection layer 30.

Optionally, as is schematically illustrated in FIG. 8, the substrate arrangement may further comprise a second metallization layer 112 attached to a second side of the dielectric insulation layer 11 opposite the first side, and a second plurality of nanowires 612 arranged on a surface of the second metallization layer 112 that faces away from the dielectric insulation layer 11, wherein the second plurality of nanowires 612 is evenly distributed over the entire surface of the second metallization layer 112 (the number of nanowires 612 per unit area is the same over the entire surface of the second metallization layer 112), and each of the second plurality of nanowires 612 comprises a first end and a second end, wherein the first end of each of the second plurality nanowires 612 is inseparably connected to the surface of the second metallization layer 112. The second plurality of nanowires 612 may be used to form a permanent connection between the substrate 10 and a heat sink or base plate 80, for example.

As has been described above, forming nanowires 612 over a (large) section or over the entire surface area of the first metallization layer 111 allows using the substrate 10 very flexibly, as it is not limited to specific designs. The nanowires 612, however, provide further advantages. As has been described with respect to FIG. 1 above, power semiconductor modules often comprise an encapsulant 5 configured to protect the components and electrical connections of the power semiconductor module, in particular the components arranged on the substrate 10 inside a housing, from certain environmental conditions and mechanical damage. A substrate arrangement comprising a substrate 10 with nanowires 612 formed thereon and an encapsulant 5 is schematically illustrated in FIG. 9.

The encapsulant 5 is generally formed after the components 20, 4 have been mounted to the substrate 10. The encapsulant 5 is formed by filling a liquid or viscous material into a housing (not specifically illustrated in FIG. 9) and by curing the originally liquid or viscous material, e.g., under the influence of heat and optionally pressure. When the liquid or viscous material of the encapsulant 5 is filled into a housing to cover the substrate 10, the material directly adjoins the free second ends of a second subset of the plurality of nanowires (the second subset including different nanowires 612 than the first subset) and also fills any gaps and spaces between the different ones of the plurality of nanowires 612 of the second subset. When curing the material, a connection is formed between the encapsulant 5 and the nanowires 612 of the second subset. That is, the encapsulant adheres to the nanowires 612 of the second subset, and therefore to the surface of the first metallization layer 111, without the need for any additional adhesion promoters.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A substrate arrangement, comprising:
a first metallization layer;
a plurality of nanowires arranged on a surface of the first metallization layer; and
at least one component arranged on the first metallization layer such that a first subset of the plurality of nanowires is arranged between the first metallization layer and the at least one component,
wherein the plurality of nanowires is evenly distributed over a section of the surface area or over the entire surface area of the first metallization layer,
wherein each of the plurality of nanowires comprises a first end and a second end,
wherein the first end of each of the plurality nanowires is inseparably connected to the surface of the first metallization layer,
wherein the second end of each nanowire of the first subset is inseparably connected to a surface of one of the at least one component such that the first subset of nanowires forms a permanent connection between the first metallization layer and the at least one component,
wherein the at least one component comprises at least one semiconductor body,
wherein the number of nanowires comprised in the first subset of nanowires is less than the number of nanowires comprised in the plurality of nanowires.

2. The substrate arrangement of claim 1, wherein the section of the surface area of the first metallization layer covered by the plurality of nanowires is between 60% and 100% of the entire surface area of the first metallization layer.

3. The substrate arrangement of claim 1, further comprising:
a dielectric insulation layer,
wherein the first metallization layer is attached to a first side of the dielectric insulation layer.

4. The substrate arrangement of claim 3, further comprising:
a second metallization layer attached to a second side of the dielectric insulation layer opposite the first side; and
a second plurality of nanowires arranged on a surface of the second metallization layer that faces away from the dielectric insulation layer,
wherein the second plurality of nanowires is evenly distributed over the entire surface of the second metallization layer,
wherein each of the second plurality of nanowires comprises a first end and a second end,
wherein the first end of each of the second plurality nanowires is inseparably connected to the surface of the second metallization layer.

5. The substrate arrangement of claim 1, wherein the first metallization layer is a structured layer comprising two or more separate sections and recesses between different sections of the first metallization layer.

6. The substrate arrangement of claim 1, wherein each of the plurality of nanowires has a diameter of between 500 nm and 1200 nm.

7. The substrate arrangement of claim 1, wherein all of the plurality of nanowires have an equal length between their first end and their second end of between 10 μm and 70 μm.

8. The substrate arrangement of claim 1, wherein the first metallization layer comprises copper, a copper alloy, aluminum, or an aluminum alloy.

9. The substrate arrangement of claim 1, wherein the plurality of nanowires comprises carbon, cobalt, copper, silicon, or gold.

10. The substrate arrangement of claim 1, further comprising:
an encapsulant directly adjoining the second ends of a second subset of the plurality of nanowires and filling any gaps and spaces between the nanowires of the second subset.

11. A method, comprising:
forming a first metallization layer;
forming a plurality of nanowires on a surface of the first metallization layer; and
arranging at least one component on the first metallization layer such that a first subset of the plurality of nanowires is arranged between the first metallization layer and the at least one component,
wherein the plurality of nanowires is evenly distributed over a section of the surface area or over the entire surface area of the first metallization layer,
wherein each of the plurality of nanowires comprises a first end and a second end,
wherein the first end of each of the plurality nanowires is inseparably connected to the surface of the first metallization layer,
wherein the second end of each nanowire of the first subset is inseparably connected to a surface of one of the at least one component such that the first subset of nanowires forms a permanent connection between the first metallization layer and the at least one component,
wherein the at least one component comprises at least one semiconductor body,
wherein the number of nanowires comprised in the first subset of nanowires is less than the number of nanowires comprised in the plurality of nanowires.

12. The method of claim 11, further comprising:
structuring the first metallization layer to form two or more separate sections and recesses between different sections of the first metallization layer.

13. The method of claim 12, wherein the first metallization layer is structured after forming the plurality of nanowires.

14. The method of claim 12, wherein the first metallization layer is structured before forming the plurality of nanowires.

15. The method of claim 14, further comprising:
after structuring the first metallization layer and before forming the plurality of nanowires, forming a masking layer in the recesses between the different sections of the first metallization layer.
